(19) United States
(12) Patent Application Publication
(10) Pub. No.: US 2026/0110859 A1
(43) Pub. Date: Apr. 23, 2026

(54) ELECTRONIC DEVICE

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW)

(73) Assignee: Advanced Semiconductor Engineering, Inc., Kaohsiung (TW)

(21) Appl. No.: 18/922,202

(22) Filed: Oct. 21, 2024

(51) Int. Cl. G02B 6/42; H01L 23/538; H01L 25/16; H01L 27/146

(52) U.S. Cl. CPC G02B 6/4214; H10F 39/024; H10F 39/8063; H10F 39/8067; H10W 70/60; H10W 70/611; H10W 90/00

(57) ABSTRACT

An electronic device is provided. The electronic device includes a carrier, a first guiding structure, and a first optical channel. The carrier has an upper surface. The first guiding structure is supported by the carrier and has a side surface extending away from the upper surface in a first direction that is non-parallel to the upper surface. The first optical channel is supported by the carrier and the side surface of the first guiding structure. The first optical channel includes a terminal end configured to receive or transmit an optical signal in the first direction.

### BACKGROUND

### 1. Technical Field

The present disclosure relates generally to an electronic device.

### 2. Description of the Related Art

Typically, a photonic component is usually optically coupled to optical fibers by edge coupling between the optical fibers and waveguides exposed by an edge of the photonic component. Therefore, it would be difficult to perform an optoelectronic inspection on a wafer-level photonic structure, which may be performed from above the wafer-level photonic structure instead of from edges thereof, unless a singulation operation is performed to expose the waveguides from edges of the singulated photonic structure. However, such process may increase the processing time and the costs.

### SUMMARY

In one or more arrangements, an electronic device includes a carrier, a first guiding structure, and a first optical channel. The carrier has an upper surface. The first guiding structure is supported by the carrier and has a side surface extending away from the upper surface in a first direction that is non-parallel to the upper surface. The first optical channel is supported by the carrier and the side surface of the first guiding structure. The first optical channel includes a terminal end configured to receive or transmit an optical signal in the first direction.

In one or more arrangements, an electronic device includes a carrier, a plurality of guiding structures, and a plurality of optical channels. The carrier has an upper surface. The guiding structures are supported by the carrier and have a plurality of side surfaces that are non-parallel to the upper surface. The optical channels extend along the side surfaces of the guiding structures and are configured to receive or transmit a plurality of optical signals. The guiding structures are configured to switch the optical signals from transmitting in a first direction to a second direction different from the first direction.

In one or more arrangements, an electronic device includes a first guiding structure, a first optical channel, a second guiding structure, and a second optical channel. The first guiding structure includes a first inclined surface. The first optical channel extends along the first inclined surface of the first guiding structure. The second guiding structure includes a second inclined surface and is located at an elevation different from the first guiding structure. The second optical channel extends along the second inclined surface of the second guiding structure.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an electronic device in accordance with some arrangements of the present disclosure.

FIG. 1B is a top view of an electronic device in accordance with some arrangements of the present disclosure.

FIG. 1C is a cross-section of an electronic device in accordance with some arrangements of the present disclosure.

FIG. 2A is a cross-section of a portion of an electronic device in accordance with some arrangements of the present disclosure.

FIG. 2B is a cross-section of a portion of an electronic device in accordance with some arrangements of the present disclosure.

FIG. 2C is a cross-section of a portion of an electronic device in accordance with some arrangements of the present disclosure.

FIG. 2D is a cross-section of a portion of an electronic device in accordance with some arrangements of the present disclosure.

FIG. 3A is a cross-section of an electronic device in accordance with some arrangements of the present disclosure.

FIG. 3B is a top view of an electronic device in accordance with some arrangements of the present disclosure.

FIG. 3C is a cross-section of an electronic device in accordance with some arrangements of the present disclosure.

FIG. 4A is a cross-section of an electronic device in accordance with some arrangements of the present disclosure.

FIG. 4B is a top view of an electronic device in accordance with some arrangements of the present disclosure.

FIG. 4C is a cross-section of an electronic device in accordance with some arrangements of the present disclosure.

FIG. 4D is a cross-section of an electronic device in accordance with some arrangements of the present disclosure.

FIG. 5A is a cross-section of an electronic device in accordance with some arrangements of the present disclosure.

FIG. 5B is a top view of an electronic device in accordance with some arrangements of the present disclosure.

FIG. 5C is a cross-section of an electronic device in accordance with some arrangements of the present disclosure.

FIG. 5D is a cross-section of an electronic device in accordance with some arrangements of the present disclosure.

FIG. 6A is a top view illustrating one or more stages of an exemplary method for manufacturing an electronic device in accordance with some arrangements of the present disclosure.

FIG. 6B is a cross-section illustrating one or more stages of an exemplary method for manufacturing an electronic device in accordance with some arrangements of the present disclosure.

FIG. 7A to FIG. 7H illustrate various stages of an exemplary method for manufacturing an electronic device in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

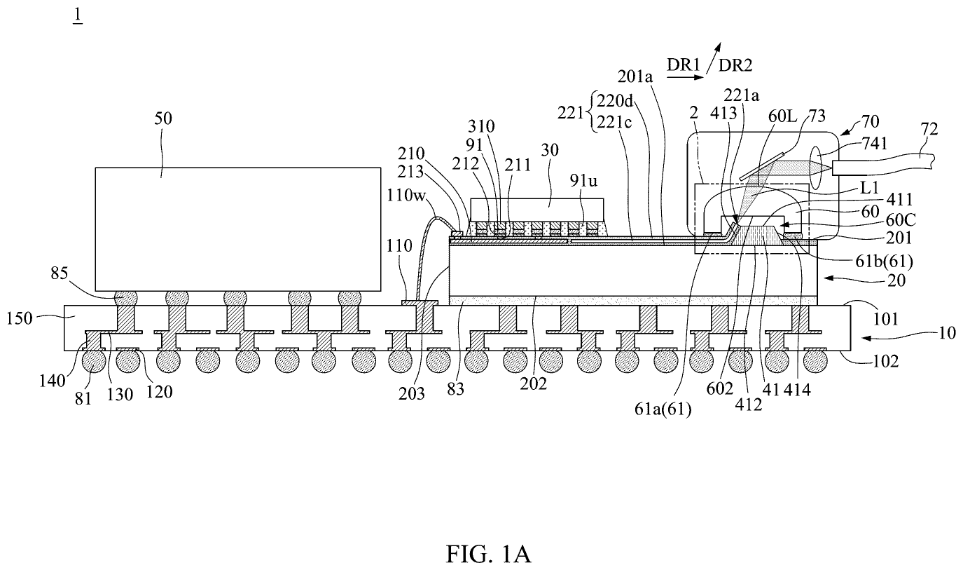

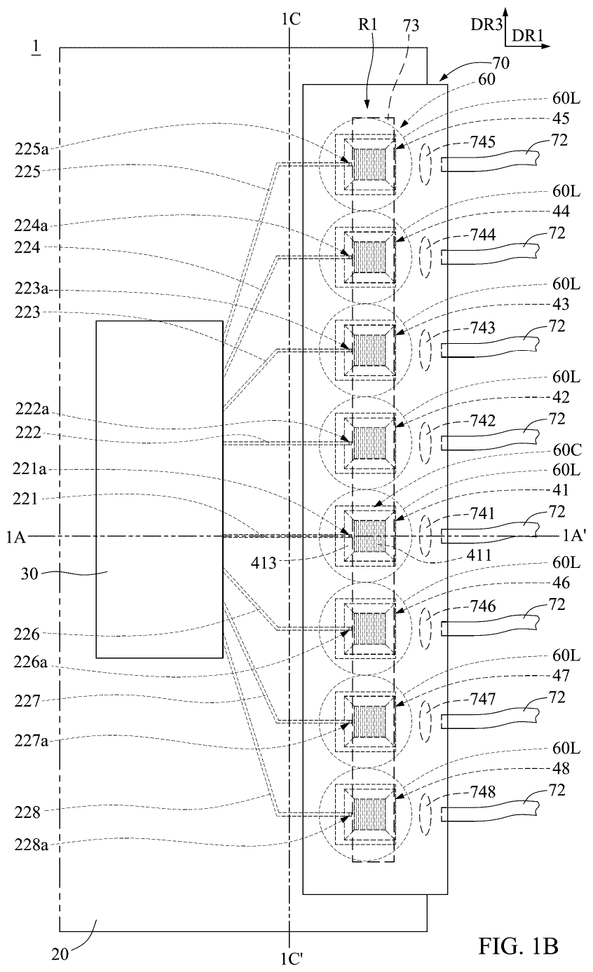

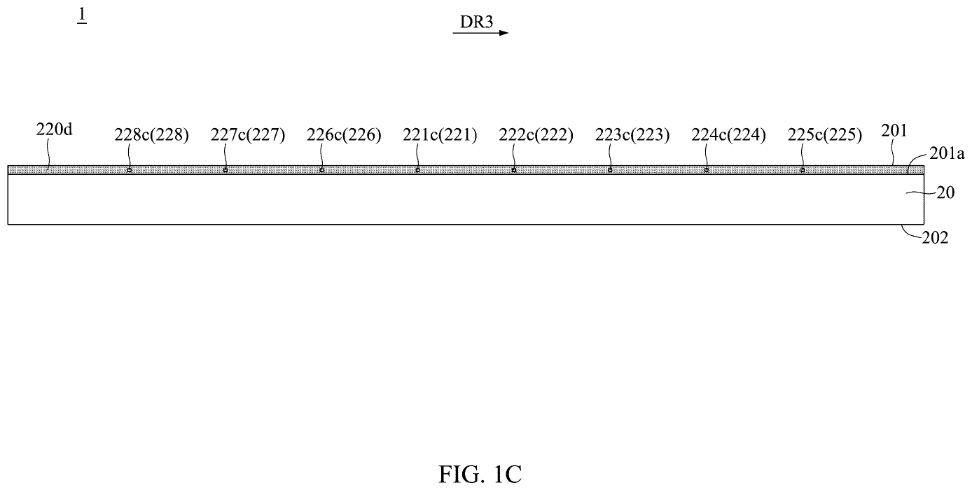

FIG. 1A is a cross-section of an electronic device 1 in accordance with some arrangements of the present disclosure. FIG. 1B is a cross-section of an electronic device 1 in accordance with some arrangements of the present disclosure. FIG. 1C is a cross-section of an electronic device 1 in accordance with some arrangements of the present disclosure. In some arrangements, FIG. 1A shows a cross-section along the line 1A-1A′ in FIG. 1B, and FIG. 1C is a cross-section along the line 1C-1C′ in FIG. 1B. The electronic device 1 may include a substrate 10, a conductive wire 110w, a photonic component 20, electronic components 30 and 50, guiding structures 41-48, an optical director 60, an optical component 70, electrical contacts 81, an adhesive element 83, and connection elements 85 and 91.

The substrate 10 may support the photonic component 20 and the electronic component 30. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces.

The substrate 10 may have a surface 101 (also referred to as a top surface or an upper surface) and a surface 102 (also referred to as a bottom surface or a lower surface) opposite to the surface 101. In some arrangements, the substrate 10 includes conductive pads 110 and 120, conductive layers 130 (or conductive traces), conductive vias 140, and a dielectric structure 150. The dielectric structure 150 may include a plurality of dielectric layers. In some arrangements, the conductive layers 130 and the conductive vias 140 that electrically connect to the conductive layers 130 and the conductive pads 110 and 120 are within the dielectric layers of the dielectric structure 150. The conductive pads 110 and 120, the conductive layers 130, and the conductive vias 140 may independently include a conductive material, such as a metal or metal alloy. Examples include gold (Au), silver (Ag), aluminum (Al), copper (Cu), or an alloy thereof. The dielectric structure 150 may include, for example, one or more organic materials (e.g., phosphoric anhydride (PA), polyimide (PI), polybenzoxazole (PBO), epoxy, and an epoxy-based material) or one or more inorganic materials (e.g., silicon oxide, silicon nitride, glass, and ceramic).

The photonic component 20 may be disposed over the substrate 10. In some arrangements, the photonic component 20 is configured to provide a photoelectric conversion. In some arrangements, the photonic component 20 is configured to communicate at least an optical signal L1 (or a modulated optical signal L1). In some arrangements, the photonic component 20 is configured to provide a photoelectric conversion of at least an optical signal L1 (or a modulated optical signal L1). The photonic component 20 may include a photonic integrated circuit (PIC), a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof. In some arrangements, the photonic component 20 supports the guiding structures 41-48. The photonic component 20 may be referred to as a carrier.

In some arrangements, the photonic component 20 includes a circuit layer 210, conductive elements 211, conductive pads 212 and 213, a dielectric structure 220d, and one or more optical channels (e.g., optical channels 221, 222, 223, 224, 225, 226, 227, and 228). The circuit layer 210 may include a combination of photonic devices, e.g., a PIC, a photodetector, a photodiode, a SOA, an optical modulator, or a combination thereof. The conductive elements 211 may include conductive traces and/or conductive vias that electrically connect the circuit layer 210 to the conductive pads 212 and 213. The dielectric structure 220d may include a plurality of dielectric layers, e.g., silicon oxide, silicon nitride, or the like. Each of the optical channel may include a core layer and a cladding covering the core layer. For example, the optical channel 221 includes a core layer 221c and a cladding (e.g., the dielectric structure 220d) covering the core layer 221c. In some arrangements, the optical channels 221-228 (or the core layers of the optical channels 221-228) are or include optical waveguides.

The photonic component 20 may have surfaces 201 and 201a (also referred to as top surfaces or upper surfaces) and a surface 202 (also referred to as a bottom surface or a lower surface) opposite to the surface 201.

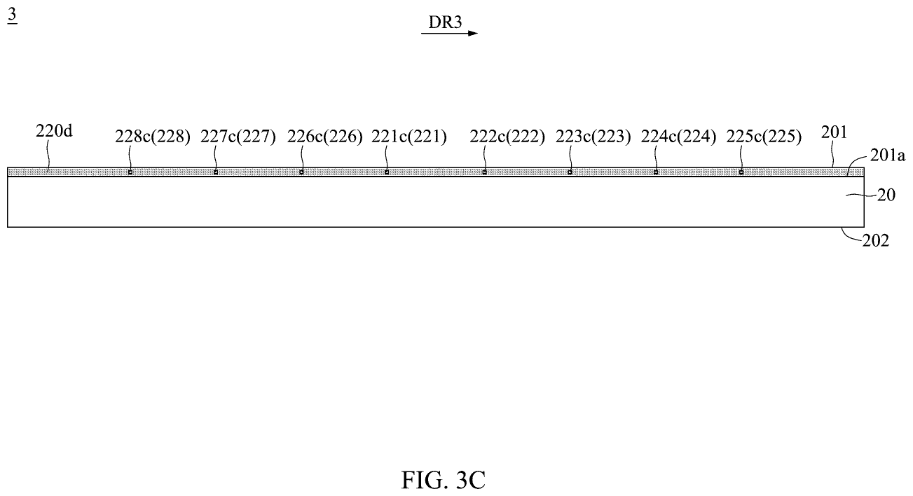

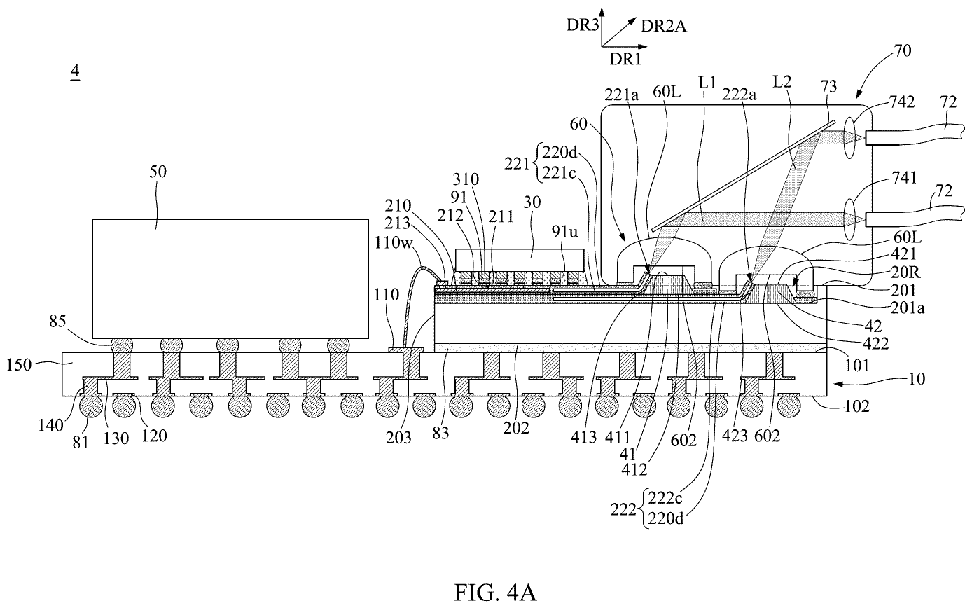

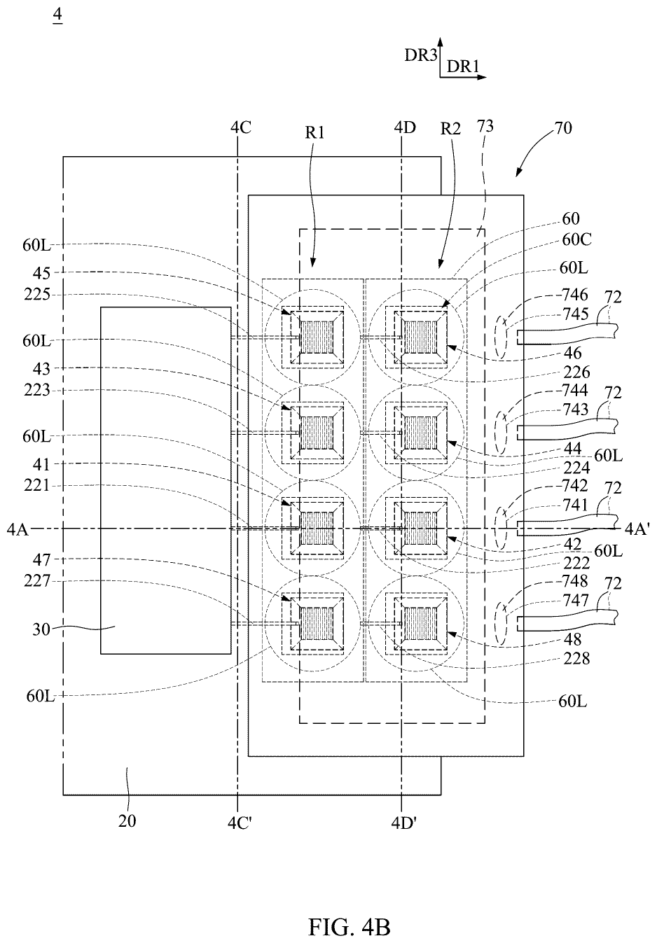

The conductive wire 110w may be disposed over the substrate 10 and electrically connect the photonic component 20 to the substrate 10. In some arrangements, the conductive wire 110w electrically connects the conductive pad 213 to the conductive pad 110. The circuit layer 210 may be configured to receive an electrical signal from the electronic component 50 through the substrate 10 and the conductive wire 110w. In some arrangements, the photonic component 20 of the electronic device 1 may include one or more conductive vias (e.g., conductive vias 20v as shown in FIG. 3A) that electrically connects the circuit layer 210 to the substrate 10. The conductive vias may penetrate the photonic component 20. The conductive vias may be or include through silicon vias (TSVs).

The electronic component 30 may be disposed over the substrate 10. In some arrangements, the electronic component 30 is disposed over and electrically connected to the photonic component 20. In some arrangements, the electronic component 30 is configured to control modulation of at least the optical signal L1. In some arrangements, the electronic component 30 is configured to amplify electrical signals. In some arrangements, the electronic component 30 is configured to amplify electrical signals received from the photonic component 20, for example, a photodetector of the photonic component 20. The electronic component 30 may include an electronic integrated circuit (EIC), which may be or include a modulator driver (DRV), a trans-impedance amplifier (TIA), or a combination thereof.

In some arrangements, the electronic component 30 includes conductive pads 310 exposed by or disposed on an active surface of the electronic component 30. In some arrangements, the electronic component 30 is electrically connected to the photonic component 20 through the connection elements 91. In some arrangements, the conductive pads 310 are electrically connected to the conductive pads 212 through the connection elements 91, and a protective element 91u further encapsulates the connection elements 91. The connection elements 91 may be or include conductive bumps, e.g., solder bumps. The protective element 91u may be or include an underfill.

The guiding structures 41, 42, 43, 44, 45, 46, 47, and 48 may be supported by the photonic component 20 (or the carrier). The guiding structures 41-48 may be supported by the photonic component 20 and have a plurality of side surfaces non-parallel to the surface 201a. The optical channels 221-228 may extend along the side surfaces of the guiding structures 41-48 and configured to receive or transmit a plurality of optical signals. The guiding structures 41-48 may be configured to switch the optical signals from transmitting in a first direction to a second direction different from the first direction. For example, one or more of the guiding structure 41-48 may be configured to switch one or more of the optical signals from transmitting in a direction DR1 substantially parallel to the surface 201a to a direction DR2A non-parallel to the surface 201a.

In some arrangements, referring to FIG. 1A, the guiding structure 41 is supported by the photonic component 20. The guiding structure 41 may have a top surface 411 (or an upper surface), a bottom surface 412 (or a lower surface), and side surfaces 413 and 414 (or lateral surfaces). In some arrangements, the side surface 413 extends away from the surface 201a (or the upper surface) of the photonic component 20 in the direction DR2A non-parallel to the surface 201a. In some arrangements, the lateral surfaces 413 may be referred to as inclined surfaces. In some arrangements, an angle formed by the side surface 413 and the surface 412 may be greater than 45° and less than 90°. In some arrangements, an angle formed by the side surface 413 and the surface 412 may be about 70° to about 80°.

In some arrangements, referring to FIG. 1A, the optical channel 221 is supported by the photonic component 20 and the side surface 413 of the guiding structure 41. In some arrangements, the optical channel 221 extends along the side surface 413 of the guiding structure 41. In some arrangements, the surface 411 (or the upper surface) the guiding structure 41 is exposed by the optical channel 221. In some arrangements, the optical channel 221 includes a terminal end 221a configured to receive or transmit an optical signal L1 in the direction DR2A. In some arrangements, the terminal end 221a of the optical channel 221 is at an elevation higher than that of the side surface 413 of the guiding structure 41 with respect to the surface 201a of the photonic component 20. In some arrangements, the terminal end 221a of the optical channel 221 is at an elevation higher than that of the surface 411 (or the top surface) of the guiding structure 41 with respect to the surface 201a of the photonic component 20. In some arrangements, the core layer 221c is spaced apart from the side surface 413 of the guiding structure 41 by the cladding (e.g., a portion of the dielectric structure 220d). In some arrangements, the core layer 221c may be or include a high refractive index material, e.g., polyimide (PI) or positive photoresist. In some arrangements, the dielectric structure 220d may be or include a low refractive index material, e.g., silicon oxide. The refractive index of the core layer 221c may be greater than the refractive index of the cladding (e.g., a portion of the dielectric structure 220d) by at least 0.1.

In some arrangements, referring to FIG. 1A and FIG. 1B, the guiding structures 41-48 are supported by the photonic component 20 (or the carrier). In some arrangements, the optical channels 221-228 are supported by the photonic component 20 and the guiding structures 41-48, respectively. In some arrangements, the electronic component 30 overlaps at least two of the guiding structures 41-48 in a direction DR1 substantially parallel to the surface 201a of the photonic component 20. In some arrangements, at least some of the guiding structures 41-48 are arranged in a row R1 and at substantially the same elevation.

Referring to FIG. 1A and FIG. 1B, each of the guiding structures 41-48 may have a side surface extending away from the surface 201a in a direction (e.g., the direction DR2A) non-parallel to the surface 201a. Each of the upper surface of the guiding structures 41-48 may be exposed by a corresponding one of the optical channels 221-228. Each of the optical channels 221-228 may include a terminal end (e.g., the terminal ends 221a, 221a, 223a, 224a, 225a, 226a, 227a, and 228a) configured to receive or transmit an optical signal in a direction (e.g., the direction DR2A) non-parallel to the surface 201a. Each of the terminal ends 221a-228a of the optical channels 221-228 may be at an elevation higher than that of the side surface of the corresponding one of the guiding structures 41-48 with respect to the surface 201a of the photonic component 20.

In some arrangements, referring to FIG. 1B, the terminal end 221a of the optical channel 221 overlaps at least one of the terminal end 222a-228a of the optical channels 222-228 in a direction DR3 substantially parallel to the surface 201a of the photonic component 20. In some arrangements, the direction DR1 is non-parallel to the direction DR3.

The electronic component 50 may be disposed over and electrically connected to the substrate 10. In some arrangements, the electronic component 50 is electrically connected to the substrate 10 through the connection elements 85. The electronic component 50 may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the electronic component 50 may be or include a processing component, e.g., an ASIC, an FPGA, a GPU, or the like, or a combination thereof. The connection elements 85 may be or include conductive bumps, e.g., solder bumps.

The optical director 60 may be disposed over the guiding structures 41-48. In some arrangements, referring to FIG. 1A and FIG. 1B, the optical director 60 includes or defines one or more lenses 60L. The lenses 60L may be convex lenses. Surfaces of the lenses 60L may be coated with a layer of ARC. In some arrangements, the cavity 60C may be defined by a substantially planar top surface (e.g., a surface 602 opposite to the surface of the lens 60L). In some arrangements, the optical director 60 includes one or more cavities 60C directly under the corresponding one or more lenses 60L. In some arrangements, each of the guiding structures 41-48 is disposed in each of the cavities 60C and directly under each of the lenses 60L. In some arrangements, referring to FIG. 1A, the beam size of an optical signal L1 transmitted from the optical channel 221 may expand, and the lens 60L is configured to collimate the optical signal L1. In some arrangements, referring to FIG. 1A and FIG. 1B, each of the lenses 60L may collimate each of the optical signals transmitted from each of the optical channels 221-228. In some arrangements, the optical director 60 is attached or connected to the photonic component 20 through an adhesive element 61. The adhesive element 61 may include portions 61a and 61b having different thicknesses from a cross-sectional view perspective. The adhesive element 61 may include a UV curable gel. The UV curable gel may be an optical gel which is transparent to the optical signals.

The optical component 70 may be optically coupled to one or more optical channels (e.g., the optical channels 221-228). In some arrangements, referring to FIG. 1A and FIG. 1B, the optical component 70 is optically coupled to the photonic component 20 through the optical channels 221-228. In some arrangements, the optical component 70 is configured to optically couple one or more optical signals (e.g., the optical signal L1) to or from the optical channels 221-228. The optical component 70 may be or include an optical fiber array unit (FAU).

In some arrangements, referring to FIG. 1A and FIG. 1B, the optical component 70 includes one or more optical fibers 72, a reflector 73, and lenses 741-748. In some arrangements, the optical fibers 72 are disposed over the photonic component 20. In some arrangements, the reflector 73 is configured to reflect one or more optical signals (e.g., the optical signal L1) to or from the optical fibers 72. In some arrangements, the lenses 741-748 are disposed between the optical fibers 72 and the reflector 73. The reflector 73 may be or include a metal layer or an anti-reflective coating (ARC). In some arrangements, referring to FIG. 1A, an optical signal L1 transmitted from the optical channel 221 may switch its transmission direction from a direction DR1 to a direction DR2A non-parallel to the surface 201a, and the beam size of the optical signal L1 transmitted from the optical channel 221 may expand and then collimated by the lens 60L of the optical director 60. Next, the collimated optical signal L1 may be reflected by the reflector 73 to switch the transmission direction from the direction DR2A to a direction (e.g., the direction DR1) different from the direction DR2A. Next, the optical signal L1 may then pass the lens 741 to converge its beam size to generate a focused optical signal L1 to be received by the optical fiber 72.

The electrical contacts 81 may be disposed on the surface 102. In some arrangements, the electrical contacts 81 electrically connect to the conductive pads 120 of the substrate 10. In some arrangements, the electrical contacts 81 include solder elements or solder balls, e.g., controlled collapse chip connection (C4) bumps, a ball grid array (BGA), or a land grid array (LGA).

The adhesive element 83 may be disposed between the photonic component 20 and the substrate 10. In some arrangements, the adhesive element 83 connects the photonic component 20 to the surface 101 of the substrate 10. The adhesive element 83 may be or include a die attach film (DAF).

In some arrangements, referring to FIG. 1C, each of the optical channels 221-228 includes a core layer (e.g., core layers 221c, 222c, 223c, 224c, 225c, 226c, 227c, and 228c). In some arrangements, the dielectric structure 220d serves as a shared cladding of the core layers 221c-228c of the optical channels 221-228. The core layers 221c-228c may be at the same elevation. The dielectric structures 220d may include a bottom dielectric layer on which the core layers 221c-228c are formed and a top dielectric layer covering the core layers 221c-228c.

According to some arrangements of the present disclosure, with the arrangements of the optical channels extending along the side surfaces of the guiding structures, optical signals can be switched from transmission in a horizontal direction (e.g., the direction DR1) to another direction (e.g., the direction DR2) non-parallel to the horizontal direction. An optoelectronic inspection by the optical component 70 can be performed before a singulation operation. Therefore, only the singulated units (e.g., photonic components 20 with the electronic components 30 disposed thereon) pass the inspection may be further connected to a substrate 10 to form the electronic device 1, and the singulated units (e.g., photonic components 20 with the electronic components 30 disposed thereon) fail the inspection may be discarded or reworked. As such, only the singulated unit considered as a “know-good-die” may be used to form the electronic device 1. Therefore, the manufacturing process of the electronic device 1 can be simplified without having to be reworked if the photonic component 20 of the singulated unit is determined to fail the inspection after singulation, and the cost can be reduced.

In addition, according to some arrangements of the present disclosure, with the arrangement of the guiding structures that direct the transmission direction of the optical channels, the electronic device 1 or the wafer-level photonic structure does not include a grating coupler but can function as a non-horizontal coupler to direct optical signals upwards from the photonic component 20. Therefore, optical signals of various wavelengths may be optically coupled from the photonic component 20 to the optical component 70, unlike grating couplers that are wavelength sensitive. Therefore, the guiding structures with the optical channels extending along the slopes (e.g., the side surface 413) of the guiding structures can support optical transmission of a relatively large wavelength range.

Moreover, according to some arrangements of the present disclosure, the beam sizes of the optical signals from the optical channels may expand until they reach the guiding structures, and then the guiding structures may be arranged with optical directors 60 (e.g., the lenses 60L) that can collimate the optical signals. Therefore, the tolerance for optical coupling can be increased.

Furthermore, according to some arrangements of the present disclosure, the terminal ends of the optical channels may be at an elevation higher than that of the top surfaces of the guiding structures. Therefore, the optical signals can be prevented from being blocked or interfered, and thus the optical transmission efficiency can be improved.

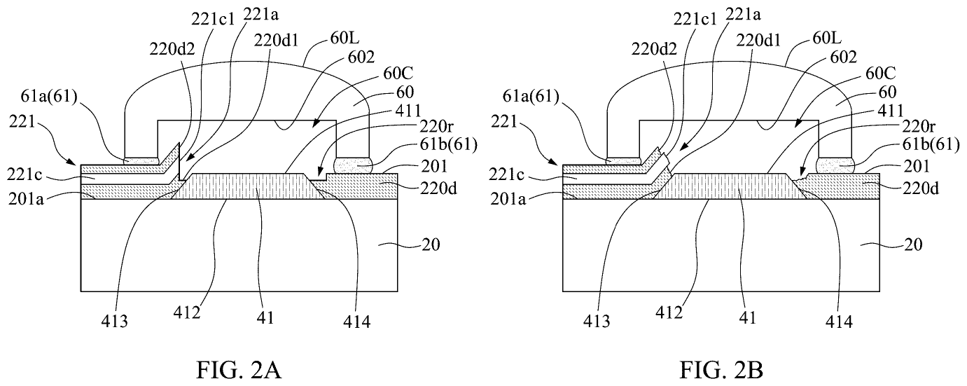

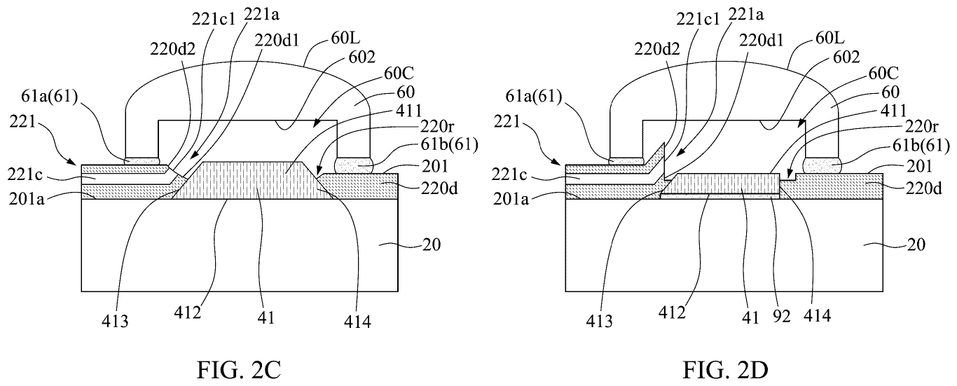

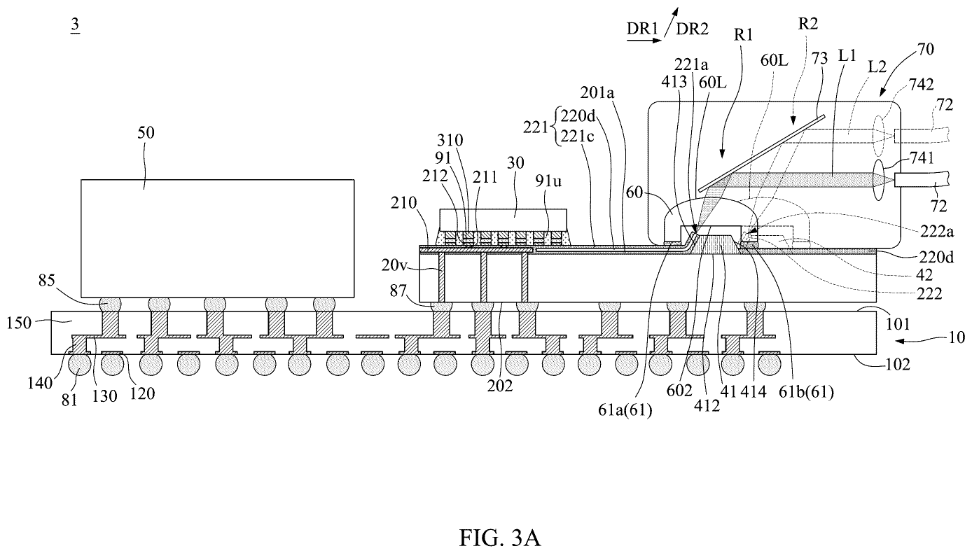

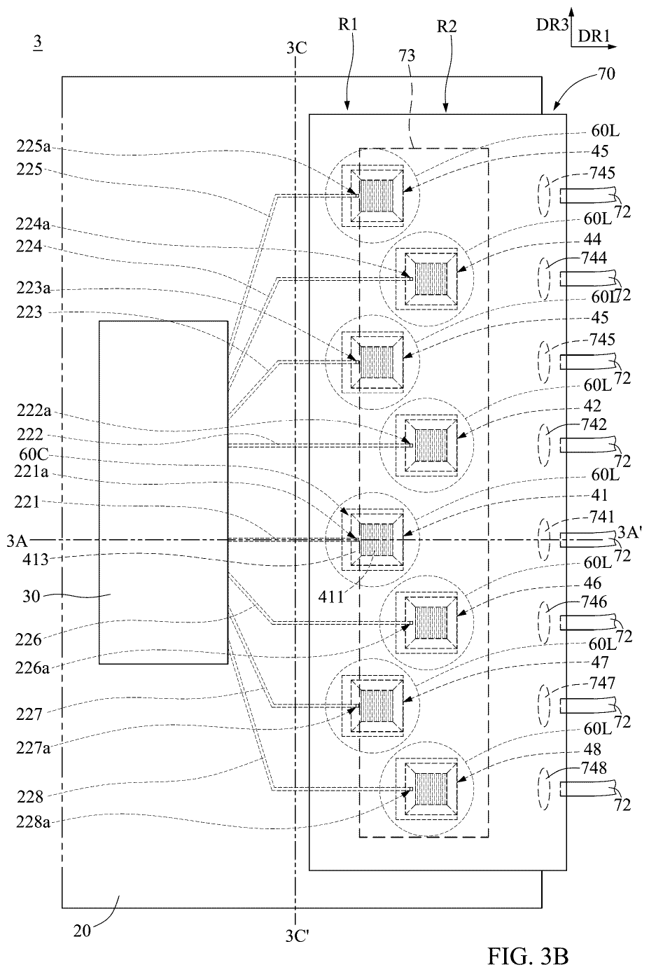

FIG. 2A is a cross-section of a portion of an electronic device in accordance with some arrangements of the present disclosure. In some arrangements, FIG. 2A shows a cross-section of a portion 2 of the electronic device 1 in FIGS. 1A-1C.

In some arrangements, the optical channel 221 has a terminal end 221a free from overlapping the surface 411 of the guiding structure 41. In some arrangements, the terminal end 221a is defined by end surfaces 220d1 and 220d2 of dielectric layers of the dielectric structure 220d and an end surface 221c1 of the core layer 221c. In some arrangements, the dielectric structure 220d further has or defines a recess 220r recessed with respect to the surface 411 of the guiding structure 41. In some arrangements, the end surface 220d1 defines a stepped cross-sectional profile. The optical channel 221 may be formed by removing portions of optical channel materials to expose the surface 411 of the guiding structure 41. The portions may be removed by a dry etching operation to form the recess 220r with substantially vertical sidewalls.

FIG. 2B is a cross-section of a portion of an electronic device in accordance with some arrangements of the present disclosure. In some arrangements, FIG. 2B shows a cross-section of a portion 2 of the electronic device 1 in FIGS. 1A-1C.

In some arrangements, the end surface 221c1 of the core layer 221c is misaligned with the end surface 220d1 and the end surface 220d2 of the cladding (e.g., the dielectric structure 220d) of the optical channel 221. In some arrangements, the end surfaces 221c1, 220d1, and 220d2 are non-planar surfaces. In some arrangements, a surface roughness of the end surfaces 221c1, 220d1, and 220d2 and a surface of the recess 220r is greater than the surface 411 of the guiding structure 41. The optical channel 221 may be formed by a dry etching operation to form the irregular surface profiles of the end surfaces 221c1, 220d1, and 220d2 and the surface of the recess 220r. The misalignment of the end surfaces 221c1, 220d1, and 220d2 may be resulted from different etching selectivity of the core layer 221c and the dielectric structure 220d to the etchant used in the dry etching operation.

FIG. 2C is a cross-section of a portion of an electronic device in accordance with some arrangements of the present disclosure. In some arrangements, FIG. 2C shows a cross-section of a portion 2 of the electronic device 1 in FIGS. 1A-1C.

In some arrangements, the end surface 221c1 of the core layer 221c is substantially misaligned with the end surface 220d1 and the end surface 220d2 of the cladding (e.g., the dielectric structure 220d) of the optical channel 221. In some arrangements, the end surfaces 221c1, 220d1, and 220d2 collectively form a substantially continuous curved surface. The optical channel 221 may be formed by a wet etching operation to form the relatively smooth and curved surface profiles of the end surfaces 221c1, 220d1, and 220d2 and the surface of the recess 220r.

FIG. 2D is a cross-section of a portion of an electronic device in accordance with some arrangements of the present disclosure. In some arrangements, FIG. 2D shows a cross-section of a portion 2 of the electronic device 1 in FIGS. 1A-1C.

In some arrangements, the guiding structure 41 is attached or connected to the photonic component 20 through an adhesive element 92. The adhesive element 92 may be or include a DAF. In some arrangements, a slope of the side surface 414 may be less than a slope of the side surface 413. The side surface 414 may be substantially vertical to the surface 201a of the photonic component 20.

FIG. 3A is a cross-section of an electronic device 3 in accordance with some arrangements of the present disclosure. FIG. 3B is a cross-section of an electronic device 3 in accordance with some arrangements of the present disclosure. FIG. 3C is a cross-section of an electronic device 3 in accordance with some arrangements of the present disclosure. In some arrangements, FIG. 3A shows a cross-section along the line 3A-3A′ in FIG. 3B, and FIG. 3C is a cross-section along the line 3C-3C′ in FIG. 3B. The electronic device 3 is similar to the electronic device 1 in FIG. 1A to FIG. 1C, and the differences therebetween are described as follows.

The electronic device 3 may further include connection elements 87. In some arrangements, the photonic component 20 includes conductive vias 20v electrically connected to the circuit layer 210. The conductive via 20v may be or include a through silicon via (TSV). In some arrangements, the photonic component 20 is electrically connected to the substrate 10 through the conductive vias 20v and the connection elements 87. The connection elements 87 may be or include conductive bumps, e.g., solder bumps.

In some arrangements, referring to FIG. 3A and FIG. 3B, the guiding structures 41-48 include the guiding structures 41, 43, 45, and 47 arranged in a row R1 and the guiding structures 42, 44, 46, and 48 arranged in a row R2 substantially parallel to the row R1. In some arrangements, the guiding structures 41, 43, 45, and 47 and the guiding structures 42, 44, 46, and 48 are staggered from a top view perspective. In some arrangements, the guiding structures 41, 43, 45, and 47 and the guiding structures 42, 44, 46, and 48 are at substantially the same elevation.

In some arrangements, referring to FIG. 3A, an optical signal L1 transmitted from the terminal end 221a of the optical channel 221 may switch its transmission direction from a direction DR1 to a direction DR2A non-parallel to the surface 201a, and the beam size of the optical signal L1 transmitted from the optical channel 221 may expand and then collimated by the lens 60L of the optical director 60 over the guiding structure 41. Likewise, an optical signal L2 transmitted from the terminal end 221a of the optical channel 222 may switch its transmission direction from a direction DR1 to a direction DR2A non-parallel to the surface 201a, and the beam size of the optical signal L2 transmitted from the optical channel 222 may expand and then collimated by the lens 60L of the optical director 60 over the guiding structure 42. Next, the collimated optical signals L1 and L2 may be reflected by the reflector 73 to switch the transmission direction from the direction DR2A to a direction (e.g., the direction DR1) different from the direction DR2A. Next, the optical signals L1 and L2 may then pass the lenses 741 and 742 to converge their beam sizes to generate focused optical signals L1 and L2 to be received by the optical fibers 72. Please be noted that the guiding structure 42, a lens 60L, the row R2, the optical signal L2, the optical channel 220, the terminal end 220a, the lens 742, and an optical fiber 72 are shown by dashed lines to merely describe the arrangements of these elements. The elements shown in dashed lines and the elements shown in solid lines are not on the same cross-section.

In some arrangements, referring to FIG. 3B, the electronic component 30 overlaps the guiding structures 41, 42, 43, and 46 in the direction DR1. In some arrangements, the terminal ends of the optical channels supported by the guiding structures in the row R1 do not overlap the terminal ends of the optical channels supported by the guiding structures in the row R2 in the direction DR3. For example, the terminal end 222a of the optical channel 222 does not overlap the terminal end 221a of the optical channel 221 and the terminal end 223a of the second optical channel 223 in the direction DR3.

According to some arrangements of the present disclosure, the guiding structures 41, 43, 45, and 47 of the row R1 and the guiding structures 42, 44, 46, and 48 of the row R2 are staggered from a top view perspective. Therefore, the area of the optical coupling region of the photonic component 20 can be reduced.

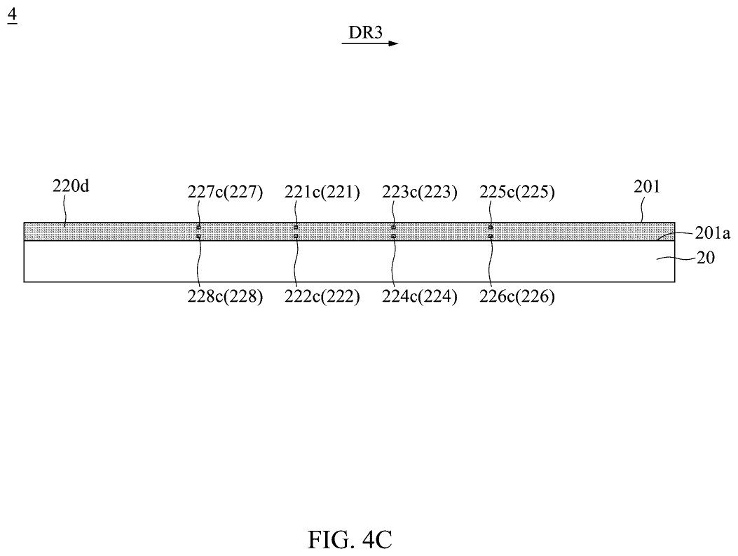

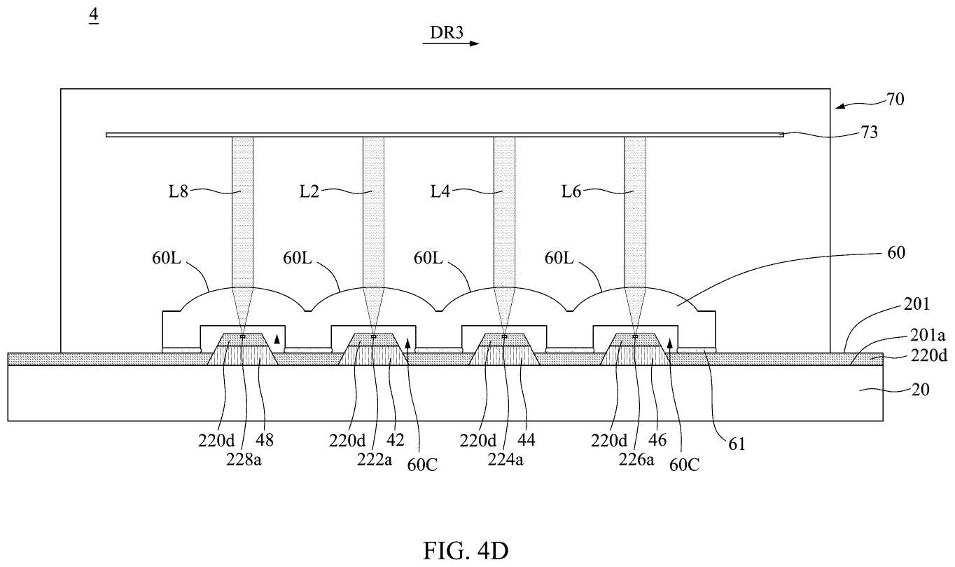

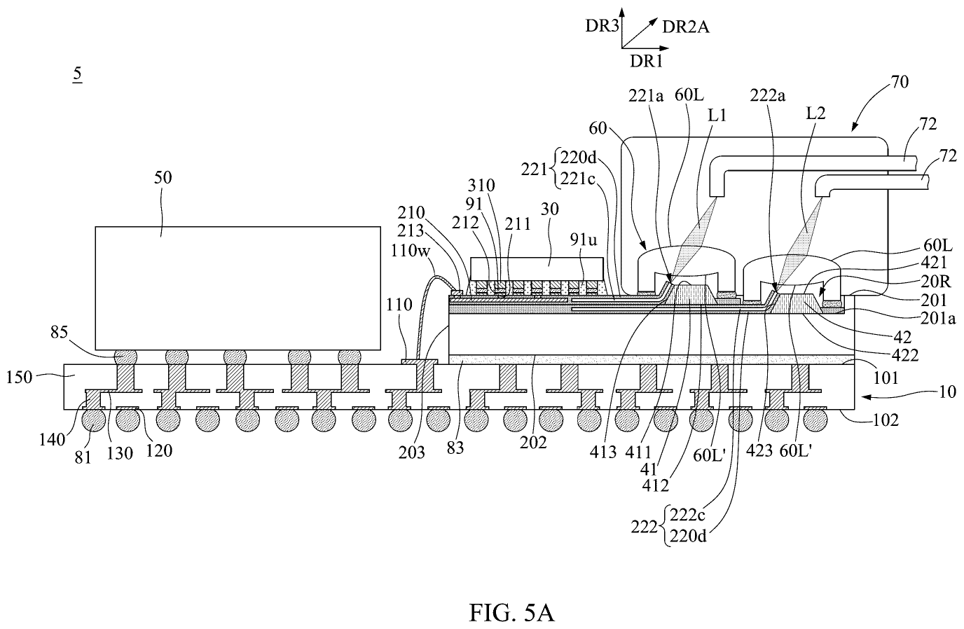

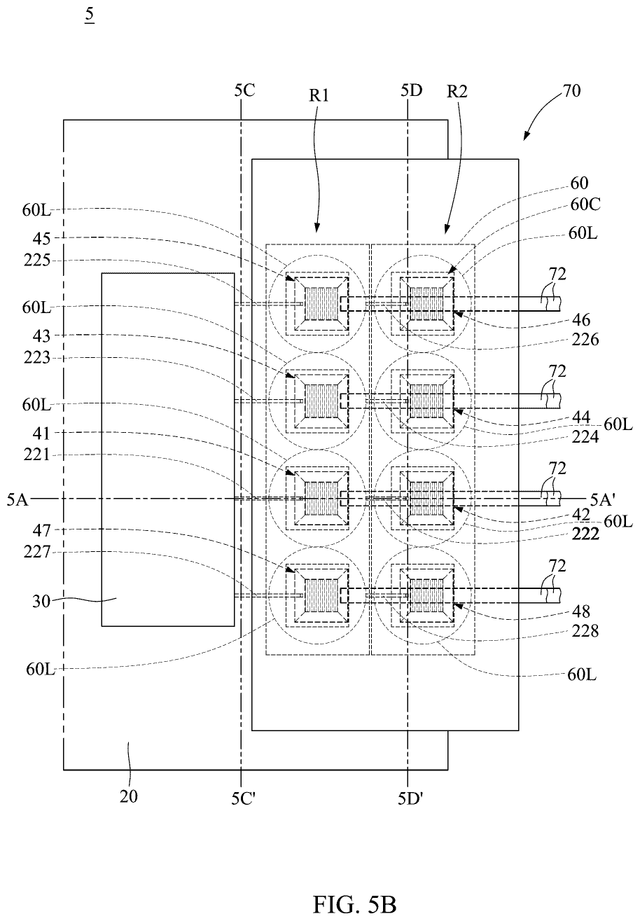

FIG. 4A is a cross-section of an electronic device 4 in accordance with some arrangements of the present disclosure. FIG. 4B is a cross-section of an electronic device 4 in accordance with some arrangements of the present disclosure. FIG. 4C is a cross-section of an electronic device 4 in accordance with some arrangements of the present disclosure. FIG. 4D is a cross-section of an electronic device 4 in accordance with some arrangements of the present disclosure. In some arrangements, FIG. 4A shows a cross-section along the line 4A-4A′ in FIG. 4B, FIG. 4C is a cross-section along the line 4C-4C′ in FIG. 4B, and FIG. 4D is a cross-section along the line 4D-4D′ in FIG. 4B. The electronic device 4 is similar to the electronic device 1 in FIG. 1A to FIG. 1C and/or the electronic device 3 in FIG. 3A to FIG. 3C, and the differences therebetween are described as follows.

In some arrangements, referring to FIG. 4A and FIG. 4B, the optical channels 221, 223, 225, and 227 extend along side surfaces of the guiding structures 41, 43, 45, and 47 and are optically coupled to a group of the optical fibers 72. In some arrangements, referring to FIG. 4A and FIG. 4B, the optical channels 222, 224, 226, 228 extend along second side surfaces of the guiding structures 42, 44, 46, and 48 and are optically coupled to another group of the optical fibers 72. In some arrangements, the two groups of the optical fibers 72 are at different elevations. In some arrangements, the photonic component 20 of the electronic device 4 may include one or more conductive vias (e.g., conductive vias 20v as shown in FIG. 3A) that electrically connects the circuit layer 210 to the substrate 10. The conductive vias may penetrate the photonic component 20. The conductive vias may be or include through silicon vias (TSVs).

In some arrangements, referring to FIG. 4C, an elevation of portions of the optical channels 221, 223, 225, and 227 is different from an elevation of portions of the optical channels 222, 224, 226, 228. In some arrangements, referring to FIG. 4C, the portions of the optical channels 221, 223, 225, and 227 overlap the portions of the optical channels 222, 224, 226, 228 from a top view perspective. In some arrangements, referring to FIG. 4B and FIG. 4C, a portion of the optical channel 221 overlaps a portion of the optical channel 222 from a top view perspective. Likewise, a portion of the optical channel 223 may overlap a portion of the optical channel 224 from a top view perspective, a portion of the optical channel 225 may overlap a portion of the optical channel 226 from a top view perspective, and a portion of the optical channel 227 may overlap a portion of the optical channel 228 from a top view perspective.

In some arrangements, referring to FIG. 4A, the guiding structure 42 is supported by the photonic component 20 and has a side surface 423 non-parallel to the surface 201a (or the upper surface). In some arrangements, the side surfaces 423 may be referred to as an inclined surface. In some arrangements, the optical channel 222 is supported by the photonic component 20 and the side surface 423 of the guiding structure 42. In some arrangements, the optical channel 222 extends along the side surface 423 of the guiding structure 42. In some arrangements, the guiding structure 41 is located at an elevation different from the guiding structure 41. In some arrangements, an elevation of a bottom surface 412 of the guiding structure 41 is different from an elevation of a bottom surface 422 of the guiding structure 42. In some arrangements, the elevation of the bottom surface 412 of the guiding structure 41 is higher than the elevation of the bottom surface 422 of the guiding structure 42. In some arrangements, the photonic component 20 supports the optical channels 221 and 222. In some arrangements, an elevation of the terminal end 222a of the optical channel 222 is different from an elevation of the terminal end 221a of the optical channel 221. In some arrangements, the elevation of the terminal end 221a of the optical channel 221 is higher than the elevation of the terminal end 222a of the optical channel 222.

In some arrangements, the photonic component 20 defines a recess 20R recessed from a top surface (e.g., the surface 201) of the photonic component 20. In some arrangements, the recess 20R accommodates a portion of the guiding structure 42. In some arrangements, referring to FIG. 4A and FIG. 4B, the guiding structures 41, 43, 45, and 47 are disposed over the surface 201, and the guiding structures 42, 44, 46, and 48 are partially within the recess 20R. In some arrangements, an elevation of the guiding structures 41, 43, 45, and 47 is different from an elevation of the guiding structures 42, 44, 46, and 48. In some arrangements, referring to FIG. 4A and FIG. 4B, the 41, 43, 45, and 47 are disposed over a portion of the optical channel 222, a portion of the optical channel 224, a portion of the optical channel 226, and a portion of the optical channel 228.

The optical component 70 may be disposed over the photonic component 20. In some arrangements, referring to FIG. 4A and FIG. 4B, the reflector 73 is configured to reflect one or more optical signals to or from the optical channels 221, 223, 225, and 227 and one or more optical signals to or from the optical channels 222, 224, 226, 228. In some arrangements, the reflector 73 overlaps the guiding structures 41-48 from a top view perspective.

In some arrangements, referring to FIG. 4A and FIG. 4B, the lens 742 is disposed over the lens 741. Likewise, the lens 744 may be disposed over the lens 743, the lens 746 may be disposed over the lens 745, and the lens 748 may be disposed over the lens 747. In some arrangements, referring to FIG. 4A and FIG. 4B, the guiding structure 41 overlaps the guiding structure 42 in a first direction (e.g., the direction DR1) substantially parallel to the surface 201a of the photonic component 20, and the lens 741 overlaps the lens 742 in a (e.g., a direction DR2) substantially perpendicular to the direction DR1.

In some arrangements, referring to FIG. 4D, the beam sizes of the optical signals L2, L4, L6, and L8 transmitted from the terminal ends 222a, 224a, 226a, and 228a of the optical channels 222, 224, 226, and 228 may expand and then collimated by the lenses 60L of the optical director 60 over the guiding structures 42, 44, 46, and 48. Next, the collimated optical signals L2, L4, L6, and L8 may be reflected by the reflector 73.

According to some arrangements of the present disclosure, portions of the optical channels 221, 223, 225, and 227 overlap portions of the optical channels 222, 224, 226, 228 from a top view perspective. Therefore, the area of the optical coupling region of the photonic component 20 can be further reduced.

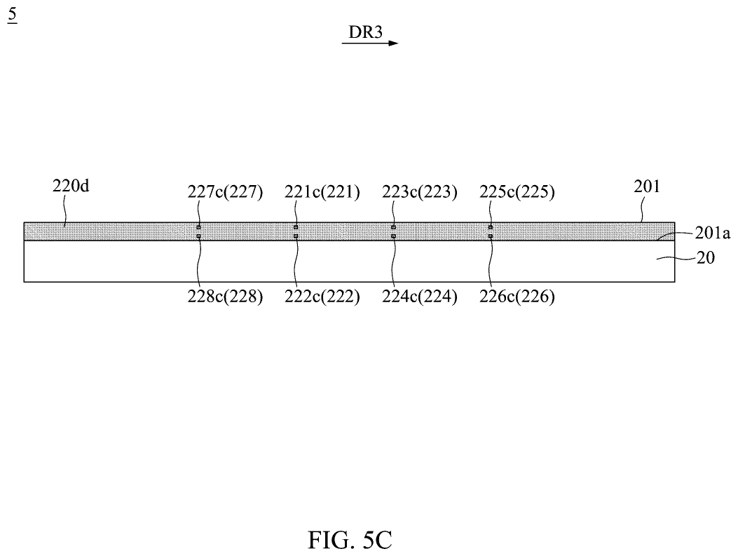

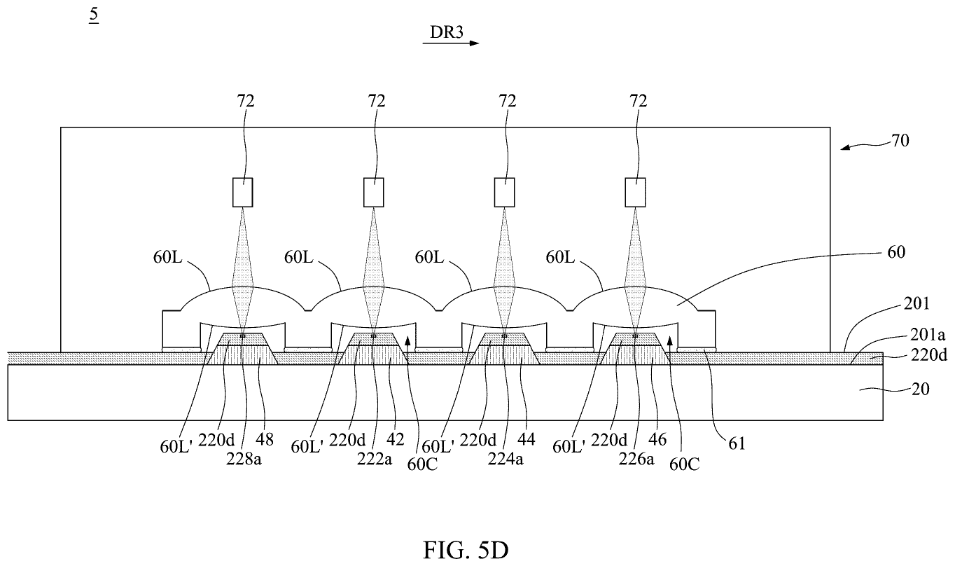

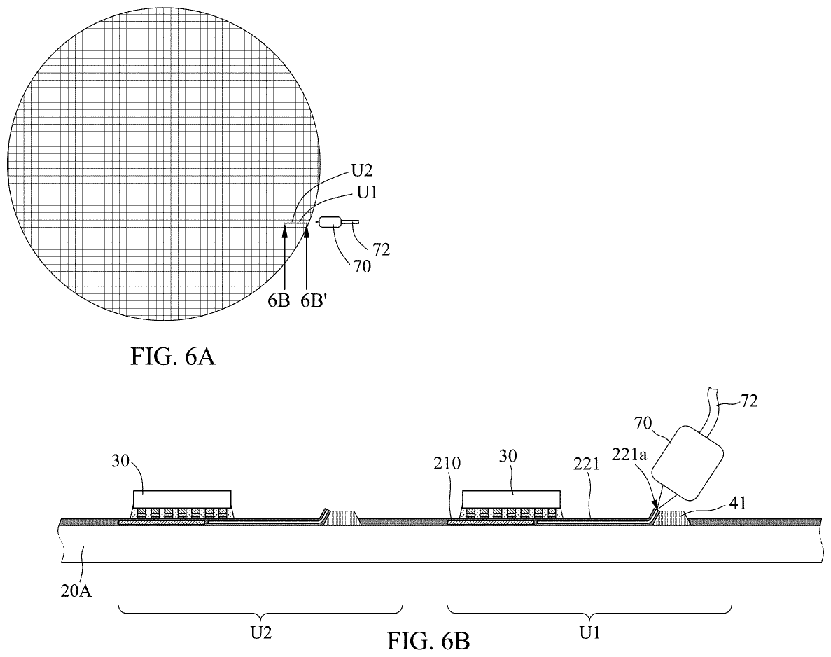

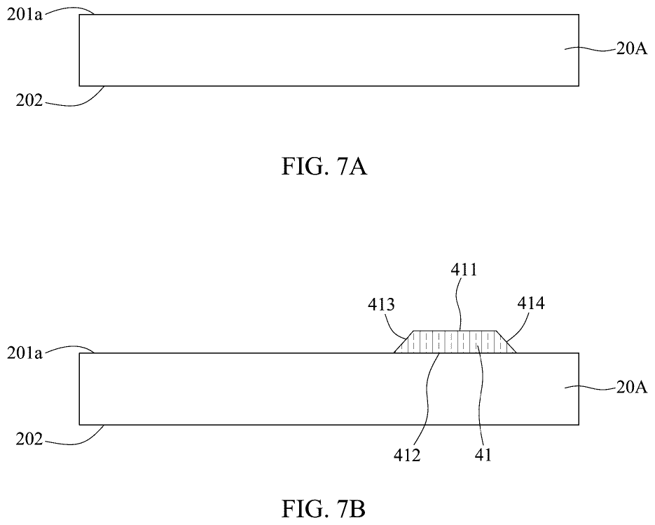

FIG. 5A is a cross-section of an electronic device 5 in accordance with some arrangements of the present disclosure. FIG. 5B is a cross-section of an electronic device 5 in accordance with some arrangements of the present disclosure. FIG. 5C is a cross-section of an electronic device 5 in accordance with some arrangements of the present disclosure. FIG. 5D is a cross-section of an electronic device 5 in accordance with some arrangements of the present disclosure. In some arrangements, FIG. 5A shows a cross-section along the line 5A-5A′ in FIG. 5B, FIG. 5C is a cross-section along the line 5C-5C′ in FIG. 5B, and FIG. 5D is a cross-section along the line 5D-5D′ in FIG. 5B. The electronic device 5 is similar to the electronic device 1 in FIG. 1A to FIG. 1C, the electronic device 3 in FIG. 3A to FIG. 3C, and/or the electronic device 4 in FIG. 4A to FIG. 4D, and the differences therebetween are described as follows.

In some arrangements, the optical component 70 includes a plurality of optical fibers 72 optically coupled to the optical channels 221-228. In some arrangements, referring to FIG. 5A and FIG. 5B, an elevation of a group of optical fibers 72 that optically couple to the optical channels 221, 223, 225, and 227 is different from an elevation of a group of the optical fibers 72 that optically coupled to the optical channels 222, 224, 226, and 228. In some arrangements, the optical fibers 72 include curved structures configured to switch transmission directions of optical signals. In some arrangements, the photonic component 20 of the electronic device 5 may include one or more conductive vias (e.g., conductive vias 20v as shown in FIG. 3A) that electrically connects the circuit layer 210 to the substrate 10. The conductive vias may penetrate the photonic component 20. The conductive vias may be or include through silicon vias (TSVs).

In some arrangements, the optical director 60 includes or defines one or more lenses 60L and one or more lenses 60L′ opposite to the lenses 60L. The lenses 60L and 60L′ may be convex lenses. In some arrangements, each of the cavities 60C is correspond to a set of the lenses 60L and 60L′. In some arrangements, the lens 60L′ the photonic component 20, and the lens 60L faces away from the photonic component 20. In some arrangements, the cavity 60C may be defined by a curved top surface (e.g., the lens 60L′). In some arrangements, each of the guiding structures 41-48 is disposed under a set of the lens 60L and the lens 60L′.

In some arrangements, referring to FIG. 5D, the beam sizes of the optical signals L2, L4, L6, and L8 transmitted from the terminal ends 222a, 224a, 226a, and 228a of the optical channels 222, 224, 226, and 228 may expand and then focused by the lenses 60L and 60L′ of the optical director 60 over the guiding structures 42, 44, 46, and 48. Next, the focused optical signals L2, L4, L6, and L8 may be transmitted to the optical fibers 72.

According to some arrangements of the present disclosure, with the design of the lenses 60L and 60L′ of the optical director 60, optical signals can be enlarged in beam sizes, collimated, and then converged in beam sizes to form focused optical signals to optically couple to the optical fibers 72. Therefore, the optical signals can be optically coupled between the photonic component 20 and the optical fibers 72, and the structure of the optical component 70 can be simplified without any reflector or focusing lenses disposed therein.

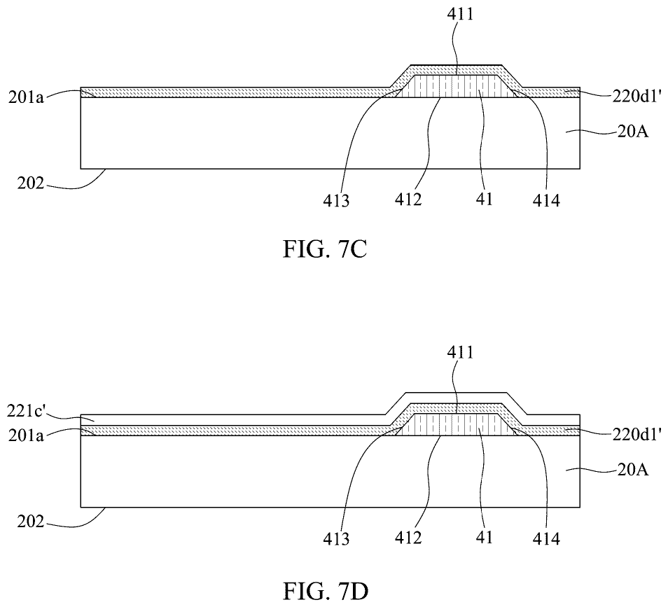

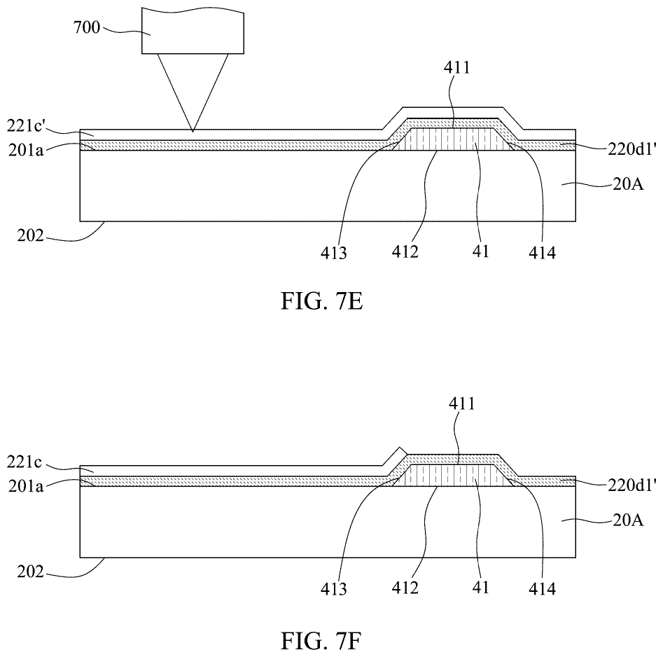

FIG. 6A is a top view illustrating one or more stages of an exemplary method for manufacturing an electronic device 1 in accordance with some arrangements of the present disclosure. FIG. 6B is a cross-section illustrating one or more stages of an exemplary method for manufacturing an electronic device 1 in accordance with some arrangements of the present disclosure. In some arrangements, FIG. 6B is a cross-section along a line 6B-6B′ in FIG. 6A.

In some arrangements, referring to FIG. 1A and FIGS. 6A-6B, a wafer-level photonic structure 20A with a plurality of guiding structures 41-48 and a plurality of optical channels 221-228 extending along side surfaces of the guiding structures 41-48 may be provided, and electronic components 30 may be electrically connected to the photonic structure 20A. The photonic structure 20A may include a plurality of units (e.g., units U1 and U2) each including an electronic component 30, a set of guiding structures 41-48, and a set of optical channels 221-228 extending along side surfaces of the set of guiding structures 41-48. Before the photonic structure 20A is singulated into singulated units (e.g., photonic components 20), an optoelectronic inspection may be performed on the wafer-level photonic structure 20A by allowing optical signals from the optical channels 221-228 of the photonic structure 20A to transmit along the sloped side surfaces of the guiding structures 41-48 so as to optically couple to the optical component 70. The inspection may be or include a detection of an amount of optical coupling. In some arrangements, a singulation operation may be performed after the inspection is performed by the optical component 70. In some arrangements, only the singulated units (e.g., photonic components 20 with the electronic components 30 disposed thereon) pass the inspection may be further connected to a substrate 10 to form an electronic device. In some arrangements, the singulated units (e.g., photonic components 20 with the electronic components 30 disposed thereon) fail the inspection may be discarded or reworked.

In some arrangements, the optical director 60 may be connected to the photonic structure 20A or the photonic component 20 permanently after or before the inspection pass, and thus the singulated unit is considered as a “know-good-die”. Therefore, the manufacturing process of the electronic device can be simplified without having to be reworked if the photonic component 20 is determined to fail the inspection after singulation, and the cost can be reduced.

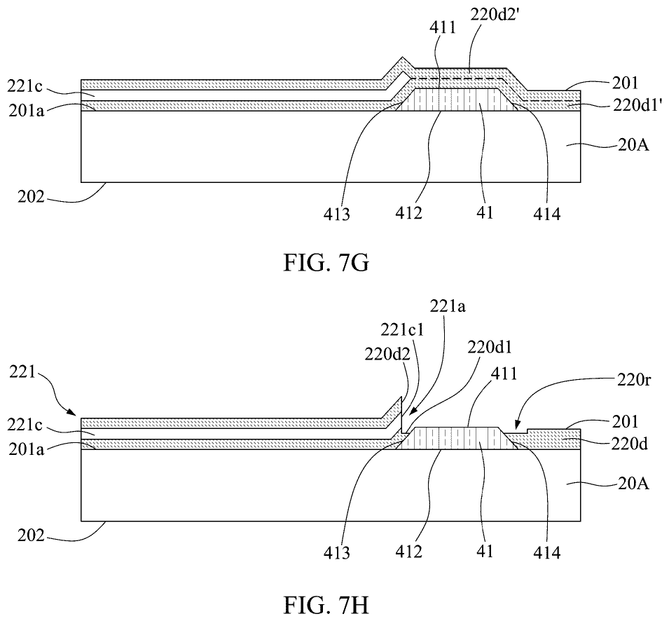

FIG. 7A to FIG. 7H illustrate various stages of an exemplary method for manufacturing an electronic device 1 in accordance with some arrangements of the present disclosure.

Referring to FIG. 7A, a wafer-level photonic structure 20A may be provided. The photonic structure 20A may have a surface 201a and a surface 202 opposite to the surface 201a.

Referring to FIG. 7B, a guiding structure 41 may be formed over the surface 201a of the photonic structure 20A. In some arrangements, a material layer is formed over the surface 201a of the photonic structure 20A, and an etching operation (e.g., a dry etching process) is performed on the material layer to form the guiding structure 41 with side surfaces 413 and 414 inclined with respect to the surface 411 and the surface 412. Please be noted that formation of one guiding structure 41 is shown in the manufacturing process as an example. The number of guiding structures formed on the photonic structures 20A may vary according to actual applications, such as depending on the number of optical channels. The arrangements of a plurality of guiding structures formed on the photonic structure 20A may be referred to the arrangements shown in FIG. 1B, FIG. 3B, FIG. 4B, and/or FIG. 5B.

In some arrangements, the guiding structure 41 may be a dummy die attached to the surface 201a of the photonic structure 20A through an adhesive element or bonded to the surface 201a of the photonic structure 20A through conductive bumps (e.g., solder bumps).

Referring to FIG. 7C, a cladding material 220d1′ may be formed over the guiding structure 41. In some arrangements, the cladding material 220d1′ is formed over the surface 441 and the side surfaces 413 and 414 of the guiding structure 41 and the surface 201a of the photonic structure 20A. The cladding material 220d1′ may be or include a low refractive index material, e.g., silicon oxide. The cladding material 220d1′ may be formed by coating.

Referring to FIG. 7D, an optical core material 221c′ may be formed over the cladding material 220d1′. In some arrangements, the optical core material 221c′ may be or include a high refractive index material, e.g., polyimide (PI) or positive photoresist. The refractive index of the optical core material 221c′ may be greater than the refractive index of the cladding material 221c′ by at least 0.1. The optical core material 221c′ may be formed by coating.

Referring to FIG. 7E, an exposure process may be performed on the optical core material 221c′. In some arrangements, a UV laser 700 may be used to expose the optical core material 221c′. In some arrangements, fine patterns may be exposed using a UV laser 700 (e.g., with a wavelength of 355 nm) without using a mask.

Referring to FIG. 7F, a wet development process may be performed on the optical core material 221c′ to remove the exposed portions so as to form one or more core layers 221c. The surface 411 of the guiding structure 41 may be exposed by the core layers 221c.

Referring to FIG. 7G, a cladding material 220d2′ may be formed over the cladding material 220d1′ and the core layer 221c. The cladding material 220d2′ may be or include a low refractive index material, e.g., silicon oxide. The cladding material 220d2′ may be formed by coating.

Referring to FIG. 7H, portions of the cladding materials 220d1′ and 220d2′ and a portion of the core layer 221c may be removed to form an optical channel 221 having a terminal end 221a and to expose the surface 411 of the guiding structure 41. In some arrangements, an etching operation may be performed to remove the portions of the cladding materials 220d1′ and 220d2′ to form a dielectric structure 220d.

Next, in some arrangements, referring to FIG. 6A and FIG. 6B, an optoelectronic inspection may be performed on the wafer-level photonic structure 20A, and then the photonic structure 20A is singulated into singulated units (e.g., photonic components 20). Next, in some arrangements, referring to FIG. 1A, the singulated unit may be disposed over and connected to a substrate 10, and an electronic component 50 may be further disposed over and connected to the substrate 10. As such, an electronic device 1 illustrated in FIG. 1A-1C may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier having an upper surface;
a first guiding structure supported by the carrier and having a side surface extending away from the upper surface in a first direction non-parallel to the upper surface; and
a first optical channel supported by the carrier and the side surface of the first guiding structure, wherein the first optical channel comprises a terminal end configured to receive or transmit an optical signal in the first direction.

2. The electronic device as claimed in claim 1, wherein an upper surface of the first guiding structure is exposed by the first optical channel.

3. The electronic device as claimed in claim 2, wherein the terminal end of the first optical channel is at an elevation higher than that of the side surface of the first guiding structure with respect to the upper surface of the carrier.

4. The electronic device as claimed in claim 1, wherein the first optical channel comprises a core layer and a cladding covering the core layer, and the core layer is spaced apart from the side surface of the first guiding structure by the cladding.

5. The electronic device as claimed in claim 4, wherein an end surface of the core layer is misaligned with an end surface of the cladding.

6. The electronic device as claimed in claim 1, wherein the carrier comprises a photonic component configured to perform a photoelectric conversion of the optical signal.

7. The electronic device as claimed in claim 1, further comprising:
an electronic component disposed over the carrier;
a second guiding structure supported by the carrier; and
a second optical channel supported by the carrier and the second guiding structure.

8. The electronic device as claimed in claim 7, wherein a terminal end of the second optical channel overlaps the terminal end of the first optical channel in a second direction substantially parallel to the upper surface of the carrier.

9. The electronic device as claimed in claim 8, wherein the electronic component overlaps the first guiding structure in a third direction non-parallel to the third direction.

10. The electronic device as claimed in claim 8, further comprising:
a third guiding structure supported by the carrier; and
a third optical channel supported by the carrier and the third guiding structure,
wherein a terminal end of the third optical channel does not overlap the terminal end of the first optical channel and the terminal end of the second optical channel in the third direction.

11. The electronic device as claimed in claim 7, wherein an elevation of a terminal end of the second optical channel is different from an elevation of the terminal end of the first optical channel.

12. The electronic device as claimed in claim 1, further comprising an optical component optically coupled to the first optical channel, wherein the optical component comprises an optical fiber over the carrier and a reflector configured to reflect the optical signal to or from the optical fiber.

13. The electronic device as claimed in claim 12, wherein the optical component further comprises a lens disposed between the optical fiber and the reflector.

14. An electronic device, comprising:
a carrier having an upper surface;
a plurality of guiding structures supported by the carrier and having a plurality of side surfaces non-parallel to the upper surface; and
a plurality of optical channels extending along the side surfaces of the guiding structures and configured to receive or transmit a plurality of optical signals,
wherein the guiding structures are configured to switch the optical signals from transmitting in a first direction to a second direction different from the first direction.

15. The electronic device as claimed in claim 14, wherein at least some of the guiding structures are arranged in a row and at substantially the same elevation.

16. The electronic device as claimed in claim 14, wherein the guiding structures comprise a plurality of first guiding structures arranged in a first row and a plurality of second guiding structures arranged in a second row substantially parallel to the first row.

17. The electronic device as claimed in claim 16, further comprising an optical component comprising a plurality of first optical fibers and a plurality of second optical fibers optically coupled to the optical channels, wherein an elevation of the first optical fibers is different from an elevation of the second optical fibers.

18. An electronic device, comprising:
a first guiding structure having a first inclined surface;
a first optical channel extending along the first inclined surface of the first guiding structure;
a second guiding structure having a second inclined surface and located at an elevation different from the first guiding structure; and
a second optical channel extending along the second inclined surface of the second guiding structure.

19. The electronic device as claimed in claim 18, further comprising a photonic component supporting the first optical channel and the second optical channel, wherein the photonic component defines a recess for accommodating a portion of the second guiding structure.

20. The electronic device as claimed in claim 18, wherein a portion of the first optical channel overlaps a portion of the second optical channel from a top view perspective.
